(19) United States
(12) Patent Application Publication
(10) Pub. No.: US 2008/0087832 A1
(43) Pub. Date: Apr. 17, 2008

(54) Radiation Detector

(75) Inventors: Kenji Sato, Kyoto (JP); Toshinori Yoshimuta, Kyoto (JP)

Correspondence Address: Cheng Law Group, PLLC, 1100 17th Street, N.W., Suite 503, Washington, DC, 20036, US

(73) Assignee: Shimadzu Corporation, Nakagyo-ku, Kyoto-shi, Kyoto-fu (JP)

(21) Appl. No.: 11/666,463

(22) PCT Filed: Sep. 30, 2005
(86) PCT No.: PCT/JP05/18144

§ 371 Date: Apr. 27, 2007

(30) Foreign Application Priority Data
Oct. 29, 2004 (JP) 2004-315527

(51) Int. Cl. H01L 31/00

(52) U.S. Cl. 250/370.01

(57) ABSTRACT

[OBJECT] To provide a radiation detector that allows a substrate with a semiconductor layer, and a light emitting device, to be attached simply.

[SOLUTION] A glass substrate 11 having an X-ray sensitive semiconductor 14 for converting incident X rays into carriers, and a planar light emitting mechanism 28 disposed on a side opposite from an X-ray incidence side of the glass substrate 11, are provided to remove carriers remaining in the X-ray sensitive semiconductor 14 by means of light emitted from the light emitting mechanism 28. Since a gel-like adhesive sheet 32 having light transmissivity is interposed between the glass substrate 11 and light emitting mechanism 28, and the light emitting mechanism 28 is planar, the glass substrate 11 and light emitting mechanism 28 can be attached simply. Since the adhesive sheet 32 interposed has light transmissivity, the light emitted from the light emitting mechanism 28 can be transmitted through the adhesive sheet 32, without being blocked, to irradiate the glass substrate 11.

### TECHNICAL FIELD

This invention relates to radiation detectors for use in the medical field, industrial field, nuclear field and so on.

### BACKGROUND ART

To describe a direct conversion type radiation detector by way of example, the radiation detector has a radiation sensitive semiconductor (semiconductor layer). The radiation sensitive semiconductor converts incident radiation into carriers (charge information), and the radiation is detected by reading the carriers converted. On a side opposite from a radiation incidence side of the semiconductor layer, a plurality of carrier collecting electrodes are arranged two-dimensionally for collecting the carriers. These radiation sensitive semiconductor, carrier collecting electrodes and so on are formed on an active matrix substrate. An uncrystallized amorphous selenium (a-Se) film, for example, is used as the radiation sensitive semiconductor. Since a thick and large film can easily be formed by a method such as vacuum deposition in the case of amorphous selenium, it is suitable for constructing a radiation detector allowing for a thick film with a large area.

When the radiation sensitive semiconductor is formed of amorphous selenium, the carriers remain in the radiation sensitive semiconductor between the carrier collecting electrodes. Such residual carriers cause a problem of producing an afterimage. In order to remove such residual carriers, a technique has been proposed for emitting light from the side opposite from the radiation incidence side during a radiation incidence operation or in time of non-irradiation (see Patent Documents 1 and 2, for example).

Generally, the active matrix substrate noted above is difficult to process, and is easy to break since it is formed of silica glass. Thus, a technique has been proposed, according to which, before forming the radiation sensitive semiconductor and carrier collecting electrodes on the active matrix substrate, a gel sheet which is a viscoelastic body having thermal conductivity is interposed between the active matrix substrate and a base material having rigidity and thermal conductivity, thereby bonding and fixing the active matrix substrate and base material beforehand (see Patent Document 3, for example). With this technique, the active matrix substrate is fixed beforehand by the base material, and bonded beforehand by the gel sheet, whereby stress and temperature distribution can be reduced in time of forming the radiation sensitive semiconductor and so on.

[Patent Document 1]

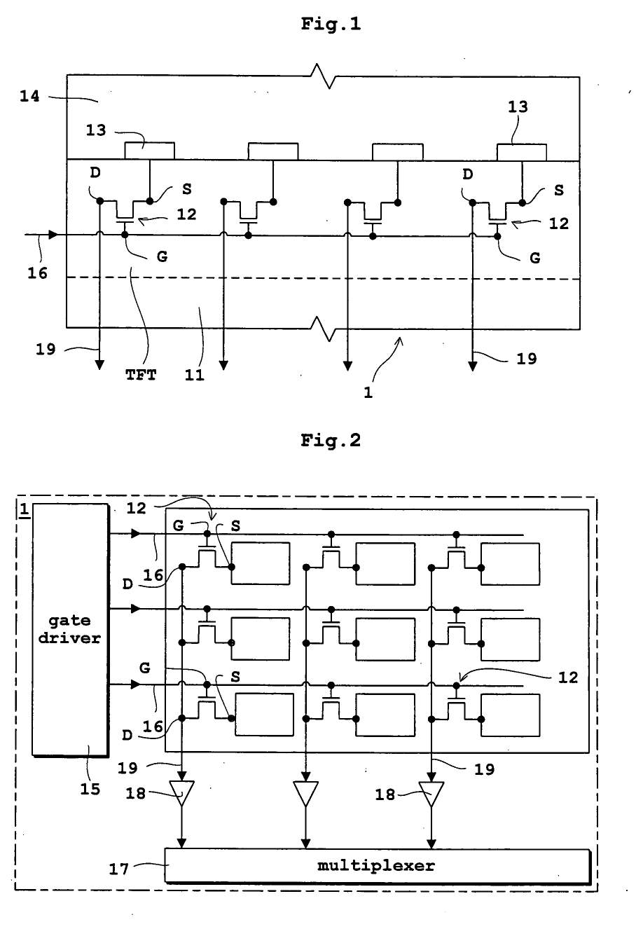

Japanese Unexamined Patent Publication No. 2004-146769 (pages 11-14, FIGS. 1-8)

[Patent Document 2]

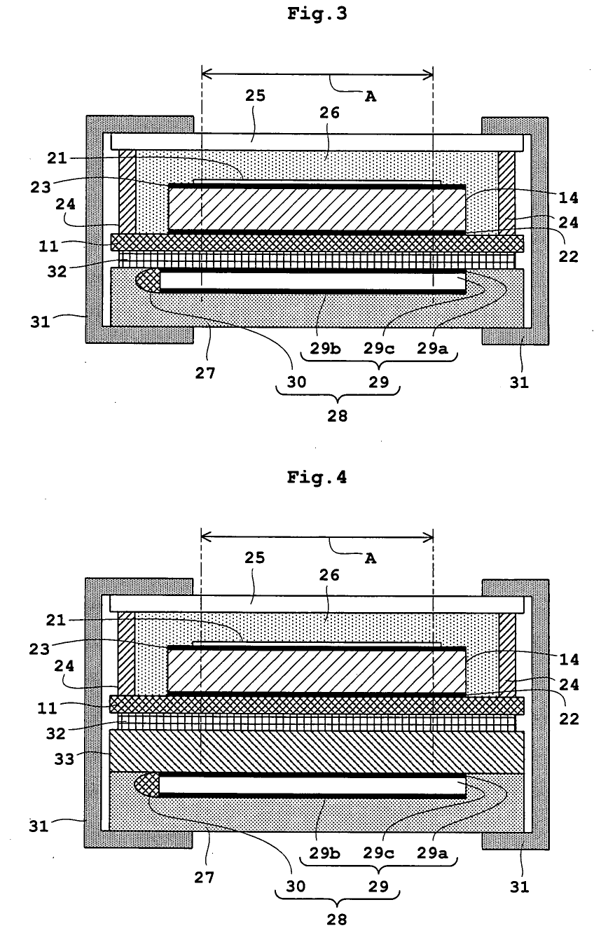

Japanese Unexamined Patent Publication No. 2000-214297 (page 6, FIGS. 3 and 4)

[Patent Document 3]

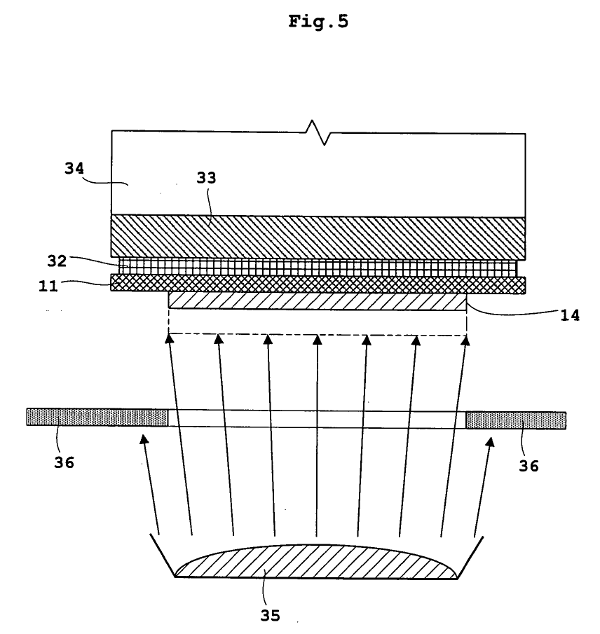

Japanese Unexamined Patent Publication No. 2001-281343 (pages 3-5, FIGS. 1 and 5)

### DISCLOSURE OF THE INVENTION

### Problem to be Solved by the Invention

However, in the technique for emitting light from the side opposite from the radiation incidence side, as in Patent Documents 1 and 2 noted above, when a light emitting device for emitting the light is disposed at the side opposite from the radiation incidence side of the active matrix substrate, it is not easy to attach the active matrix substrate and light emitting device.

This invention has been made in view of such a situation, and its object is to provide a radiation detector that allows a substrate with a semiconductor layer, and a light emitting device, to be attached simply.

### Means for Solving the Problem

In order to solve the above problem, Inventors have attained the following findings. That is, with attention focused on Patent Document 3 noted above, it has been conceived to combine Patent Documents 1 and 2 and Patent Document 3. However, to combine them simply will produce the following adverse effect. That is, when a substrate represented by an active matrix substrate and a light emitting device are attached with a base material or gel sheet interposed in between, it is possible to reduce the stress and temperature distribution occurring in time of forming a semiconductor layer represented by a radiation sensitive semiconductor on the active matrix substrate. However, the light emitted from the light emitting device will be blocked by the base material or gel sheet. It has been found then that the material to be interposed, such as the base material or gel sheet, may be formed of a material having light transmissivity.

Based on such findings, this invention provides the following construction.

The invention set out in claim 1 provides a radiation detector comprising a substrate having a semiconductor layer operable in response to incident radiation for converting information on said radiation into charge information, and a planar light emitting device formed on a side opposite from a radiation incidence side of the substrate, said radiation detector detecting the radiation by reading converted charge information, and removing charge information remaining in said semiconductor layer by means of light emitted from said light emitting device, characterized in that said substrate and light emitting device are attached with a substance having light transmissivity interposed therebetween.

[Functions and Effects] According to the invention set out in claim 1, a substrate having a semiconductor layer operable in response to incident radiation for converting information on the radiation into charge information, and a planar light emitting device formed on a side opposite from a radiation incidence side of the substrate, are provided to detect the radiation by reading converted charge information, and to remove charge information remaining in the above semiconductor layer by means of light emitted from the above light emitting device. At this time, since a sub-stance having light transmissivity is interposed between the above substrate and light emitting device, and the light emitting device is planar, the substrate with the semiconductor layer and the light emitting device can be attached simply. Since the substance interposed has light transmissivity, the light emitted from the light emitting device can be transmitted through the substance having light transmissivity, without being blocked, to irradiate the substrate.

In the above invention, one example of the substance having light transmissivity is a gel-like adhesive sheet, the adhesive sheet being interposed between the substrate and the light emitting device, to attach the substrate and the light emitting device as fixedly adhering to each other (the invention set out in claim 2). The adhesive sheet is free from omission of adhesion and bubbles contained that occur with a liquid adhesive, and allows for uniform irradiation with the light from the light emitting device, while maintaining bonding capability. The gel-like state assures excellent shock absorption also.

Another example of the substance having light transmissivity is a plate having planar opposite surfaces, the plate being interposed between the substrate and the light emitting device, to attach the substrate and the light emitting device as fixed to each other (the invention set out in claim 3). In the case of the plate, the interposition of the plate can promote mechanical strength.

A further example of the substance having light transmissivity includes a gel-like adhesive sheet, and a plate having planar opposite surfaces, the adhesive sheet being interposed between the substrate and the plate, to attach the substrate and the plate as fixedly adhering to each other, and the plate being interposed between the substrate and the light emitting device, to attach the substrate and the light emitting device as fixed to each other (the invention set out in claim 4). The adhesive sheet and plate constitute an invention combining the invention set out in claim 2 and the invention set out in claim 3 described above. Therefore, the functions and effects of the respective inventions are produced in combination. That is, the adhesive sheet interposed between the substrate and plate is free from omission of adhesion and bubbles contained that occur with a liquid adhesive, and allows for uniform irradiation with the light from the light emitting device, while maintaining bonding capability between the substrate and plate. The gel-like state assures excellent shock absorption also. Further, the plate interposed between the substrate and light emitting device can promote mechanical strength.

Where the substance having light transmissivity is a plate (the invention set out in claim 3 or 4), it is preferred that the plate has a roughened surface opposed to the substrate (the invention set out in claim 5). Even if bubbles are contained between the plate and substrate, light can be transmitted uniformly without boundaries of the bubbles becoming conspicuous, since the light is scattered about in multiple directions by the roughened surface.

In the above invention, one example of the light emitting device includes a planar light guide device, and a linear light emitting device disposed at an end thereof, the above light guide device having a light diffusing sheet opposed to the substrate, a light reflecting sheet disposed on a side remote from the substrate, and a transparent plate held between these sheets (the invention set out in claim 6). Each ray of linear light emitted from the linear light emitting device, while proceeding through the transparent plate, is reflected by the light reflecting sheet toward the substrate, and while being diffused by the light diffusing sheet, is emitted to the substrate and also to the semiconductor layer. The light emitting device includes the light guide device having such sheets and transparent plate, and the linear light emitting device. Thus, the planar light emitting device can be formed thin.

Where the light emitting device includes the planar light guide device and linear light emitting device (the invention set out in claim 6), it is preferred that the light diffusing sheet has a roughened surface (the invention set out in claim 7). Even if bubbles are contained in the side of the light diffusing sheet opposed to the substrate (or between the light diffusing sheet and adhesive sheet when depending from claim 2 or 4), light can be transmitted uniformly without boundaries of the bubbles becoming conspicuous, since the light is scattered about in multiple directions by the roughened surface.

In the above invention, it is preferred that the sub-stance having light transmissivity is formed of a material of higher thermal conductivity than the substrate (the invention set out in claim 8). The substance having light transmissivity formed of a material of high thermal conductivity is attached to the substrate beforehand whereby stress and temperature distribution can be reduced in time of forming the semiconductor layer on the substrate.

This specification discloses also an invention relating to a radiation detector manufacturing method for manufacturing the following radiation detector.

(1) A method of manufacturing a radiation detector comprising a substrate having a semiconductor layer operable in response to incident radiation for converting information on said radiation into charge information, and a planar light emitting device formed on a side opposite from a radiation incidence side of the substrate, said radiation detector detecting the radiation by reading converted charge information, and removing charge information remaining in said semiconductor layer by means of light emitted from said light emitting device, characterized in that said substrate and light emitting device are attached with, interposed therebetween, a substance having light transmissivity and higher thermal conductivity than the substrate, said semiconductor layer is laminated on the substrate after the attachment, and the light emitting device is attached thereafter.

According to the invention set out in (1) above, the substance having light transmissivity formed of a material of high thermal conductivity is attached to the substrate beforehand whereby stress and temperature distribution can be reduced in time of forming the semiconductor layer on the substrate.

(2) A method of manufacturing a radiation detector as defined in (1) above, characterized in that the substance having light transmissivity includes a gel-like adhesive sheet, and a plate having planar opposite surfaces.

According to the invention set out in (2) above, the adhesive sheet used is free from omission of adhesion and bubbles contained that occur with a liquid adhesive, and allows for uniform irradiation with the light from the light emitting device, while maintaining bonding capability. The gel-like state assures excellent shock absorption also. Further, the plate used can promote mechanical strength.

### EFFECTS OF THE INVENTION

In the radiation detector according to this invention, a substance having light transmissivity is interposed between the above substrate and light emitting device, and the light emitting device is planar. Consequently, the substrate with the semiconductor layer and the light emitting device can be attached simply.

### BRIEF DESCRIPTION OF THE DRAWINGS

[FIG. 1]

Equivalent circuit, in side view, of a flat panel type X-ray detector in Embodiments 1 and 2.

[FIG. 2]

Equivalent circuit, in plan view, of the flat panel type X-ray detector in Embodiments 1 and 2.

[FIG. 3]

Sectional view of the flat panel type X-ray detector in Embodiment 1.

[FIG. 4]

Sectional view of the flat panel type X-ray detector in Embodiment 2.

[FIG. 5]

Sectional view of the flat panel type X-ray detector in a manufacturing process.

### DESCRIPTION OF REFERENCES

1 . . . flat panel type X-ray detector (FPD)
11 . . . glass substrate
14 . . . X-ray sensitive semiconductor
28 . . . light emitting mechanism
29 . . . light guide
29a . . . light diffusing sheet
29b . . . light reflecting sheet
29c . . . transparent plate
30 . . . linear light emitter
32 . . . adhesive sheet
33 . . . plate

### BEST MODE FOR CARRYING OUT THE INVENTION

### Embodiment 1

Embodiment 1 of this invention will be described hereinafter with reference to the drawings.

FIG. 1 is an equivalent circuit, in side view, of a flat panel type X-ray detector in Embodiment 1. FIG. 2 is an equivalent circuit, in plan view, of the flat panel type X-ray detector. FIG. 3 is a sectional view of the flat panel type X-ray detector. In Embodiment 1, including Embodiment 2 described hereinafter, a radiation detector will be described by taking a flat panel X-ray detector of the direct conversion type (hereinafter called “FPD” as appropriate) for example.

As shown in FIG. 1, an FPD 1 includes a glass substrate 11, and a thin-film transistor TFT formed on the glass substrate 11. As shown in FIGS. 1 and 2, the thin-film transistor TFT has numerous (e.g. 1028×1028) switching elements 32 formed in a two-dimensional matrix arrangement of columns and rows. The switching elements 12 are separated from one another for respective carrier collecting electrodes 13. That is, FPD 1 is also a two-dimensional array radiation detector. The glass substrate 11 corresponds to the substrate in this invention.

As shown in FIG. 1, an X-ray sensitive semiconductor 14 is laminated on the carrier collecting electrodes 13. As shown in FIGS. 1 and 2, the carrier collecting electrodes 13 are connected to sources S of the switching elements 12. A gate driver 15 has a plurality of gate bus lines 16 connected thereto, and each gate bus line 16 is connected to gates G of the switching elements 12. On the other hand, as shown in FIG. 2, a multiplexer 17 that collects charge signals for output as one has a plurality of data bus lines 19 connected thereto through amplifiers 18. As shown in FIGS. 1 and 2, each data bus line 19 is connected to drains D of the switching elements 12. The X-ray sensitive semiconductor 14 corresponds to the semiconductor layer in this invention.

In this way, the thin-film transistor TFT and X-ray sensitive semiconductor 14 are laminated on the glass substrate 11, and the switching elements 12 and carrier collecting electrodes 13 are pattern-formed in the two-dimensional matrix arrangement on the glass substrate 11. Such glass substrate 11 is also called an “active matrix substrate”.

With a bias voltage applied to a common electrode not shown, the gates of the switching elements 2 are turned on by applying thereto a voltage of the gate bus lines 16 (or reducing it to 0V). The carrier collecting electrodes 13 read charge signals (carriers) converted from X rays incident on the detecting surface through the X-ray sensitive semiconductor 14, onto the data bus lines 19 through the sources S and drains D of the switching elements 12. Until the switching elements are turned on, the charge signals are provisionally accumulated and stored in capacitors (not shown). The charge signals read onto the respective data bus lines 19 are amplified by the amplifiers 18, and outputted collectively as one charge signal from the multiplexer 17. The outputted charge signal is digitized by an analog-to-digital converter not shown, and outputted as an X-ray detection signal. The analog-to-digital converter may be disposed upstream of the multiplexer 17.

Next, a specific construction of FPD 1 will be described with reference to FIG. 3. The X-ray sensitive semiconductor 14 is laminated on the glass substrate 11 noted above, and the common electrode (voltage application electrode) 21 is further laminated on the X-ray sensitive semiconductor 14. As the X-ray sensitive semiconductor 14, for example, an amorphous semiconductor represented by uncrystallized amorphous selenium (a-Se) or a compound semiconductor represented by CdZnTe, is used. As shown in FIG. 3, a carrier selective high resistance film 22 may be formed between the glass substrate 11 and X-ray sensitive semiconductor 14 (more precisely, on the side of X-ray sensitive semiconductor 14 rather than the carrier collecting electrodes 13 shown in FIG. 1), and a carrier selective high resistance film 23 may be formed between the X-ray sensitive semiconductor 14 and common electrode 21.

Where a positive bias voltage is applied to the common electrode 21, a material with a large contribution of electrons is used for the carrier selective high resistance film 23. This inhibits entry of holes from the common electrode 21 to reduce dark current. A material with a large contribution of holes is used for the carrier selective high resistance film 22. This inhibits entry of electrons from the carrier collecting electrodes 13 to reduce dark current.

Conversely, where a negative bias voltage is applied to the common electrode 21, a material with a large contribution of holes is used for the carrier selective high resistance film 23. This inhibits entry of electrons from the common electrode 21 to reduce dark current. A material with a large contribution of electrons is used for the carrier selective high resistance film 22. This inhibits entry of holes from the carrier collecting electrodes 13 to reduce dark current.

It is not absolutely necessary to form the carrier selective high resistance films 22 and 23. One or both of the high resistance films 22 and 23 may be omitted.

Spacers 24 are erected on the periphery of the glass substrate 11, and an insulating plate 25 is disposed to be supported by the spacers 24. A curable synthetic resin 26 is poured and enclosed in a space surrounded by the glass substrate 11, spacers 24 and insulating plate 25.

On the other hand, a holding base 27 is disposed on the side opposite from the radiation incidence side of the glass substrate 11, i.e. the side facing away from the X-ray sensitive semiconductor 14. The holding base 27 has a planar light emitting mechanism 28 embedded and accommodated in an effective pixel area A.

The light emitting mechanism 28 is constructed to emit light toward the X-ray incidence side. Specifically, the light emitting mechanism 28 includes a planar light guide 29, and a linear light emitter 30 disposed at an end thereof. The light guide 29 has a light diffusing sheet 29a disposed adjacent the glass substrate 11, a light reflecting sheet 29b disposed remote from the glass substrate 11, and a transparent plate 29c held between these sheets 29a and 29b. The light diffusing sheet 29a has a roughened surface to be what is called “ground glass”. Each ray of linear light emitted from the linear light emitter 30, while proceeding through the transparent plate 29c, is reflected by the light reflecting sheet 29b toward the glass substrate 11 (i.e. toward the X-ray incidence side), and while being diffused by the light diffusing sheet 29a, is emitted to the glass substrate 11 and also to the X-ray sensitive semiconductor 14. The light emitting mechanism 28 corresponds to the light emitting device in this invention. The light guide 29 corresponds to the light guide device in this invention. The linear light emitter 30 corresponds to the linear light emitting device in this invention. The light diffusing sheet 29a corresponds to the light diffusing sheet in this invention. The light reflecting sheet 29b corresponds to the light reflecting sheet in this invention. The transparent plate 29c corresponds to the transparent plate in this invention.

Clamps 31 support, so as to sandwich, peripheries of the holding base 27 accommodating the light emitting mechanism 28 and the insulating plate 25 noted above. The clamps 31 can reinforce the glass substrate 11, light emitting mechanism 28 and so on in an assembled state.

A transparent or translucent gel-like adhesive sheet 32 is interposed between the glass substrate 11 and light emitting mechanism 28. By interposing the adhesive sheet 32 between the glass substrate 11 and light emitting mechanism 28, the glass substrate 11 and adhesive sheet 32 are attached as fixedly bonded together. The adhesive sheet 32 needs only to be transparent or translucent, i.e. needs only to be a material having light transmissivity. It is preferred to form the adhesive sheet 32 with a material of higher thermal conductivity than the glass substrate 11. For the adhesive sheet 32, a silicon resin having a powder of alumina (Al₂O₃) or silica (SiO₂) added thereto is used.

The adhesive sheet 32 need not be transparent or translucent throughout the entire area thereof, but may be transparent or translucent only in the effective pixel area A requiring light emission from the light emitting mechanism 28. It is not absolutely necessary to be transparent or translucent in the peripheral parts other than the effective pixel area A. For example, the adhesive sheet 32 used may be colored in the peripheral parts other than the effective pixel area A. Of course, the adhesive sheet 32 used may be transparent or translucent also in the peripheral parts other than the effective pixel area A. The gel-like adhesive sheet 32 corresponds to the adhesive sheet in this invention, and corresponds also to the substance having light transmissivity in this invention.

According to the FPD 1 in Embodiment 1 constructed as described above, the glass substrate 11 has the X-ray sensitive semiconductor 14 for converting information on X rays into carriers which are charge information in response to an incidence of X rays, and the planar light emitting mechanism 28 is disposed on the side opposite from the X-ray incidence side of the glass substrate 11. Thus, X rays are detected by reading the converted carriers, and the carriers remaining in the above X-ray sensitive semiconductor 14 are removed by the light emitted from the above light emitting mechanism 28. At this time, since the gel-like adhesive sheet 32 which is a substance having light transmissivity is interposed between the above glass substrate 11 and light emitting mechanism 28, and since the light emitting mechanism 28 is planar, the glass substrate 11 having the X-ray sensitive semiconductor 14 and the light emitting mechanism 28 can be attached simply. Further, since the adhesive sheet 32 interposed has light transmissivity, the light emitted from the light emitting mechanism 28 can, without being blocked, pass through the adhesive sheet 32 having light transmissivity, to irradiate the glass substrate 11.

In Embodiment 1, the substance having light transmissivity is the gel-like adhesive sheet 32 as noted above. The adhesive sheet 32 is free from omission of adhesion and bubbles contained that occur with a liquid adhesive, and allows for uniform irradiation with the light from the light emitting mechanism 28, while maintaining bonding capability. The gel-like state assures excellent shock absorption also.

In Embodiment 1, the light emitting mechanism 28 includes the light guide 29 having the light diffusing and light reflecting sheets 29a and 29b and the transparent plate 29c, and the linear light emitter 30. Thus, the planar light emitting mechanism 28 can be formed thin. In Embodiment 1, the surface of the light diffusing sheet 29a is roughened. Thus, even if bubbles are contained in the side of the light diffusing sheet 29a opposed to the glass substrate 11 (between the light diffusing sheet 29a and adhesive sheet 32 in Embodiment 1), light can be transmitted uniformly without boundaries of the bubbles becoming conspicuous, since the light is scattered about in multiple directions by the roughened surface.

### Embodiment 2

Embodiment 2 of this invention will be described next with reference to the drawings.

FIG. 4 is a sectional view of a flat panel type X-ray detector (FPD) in Embodiment 2. Parts common to Embodiment 1 are affixed with like reference numerals, and will not be illustrated or described again. The glass substrate 11 and X-ray sensitive semiconductor 14, and the pattern formation of switching elements 12 and carrier collecting electrodes 13, are the same as in FIGS. 1 and 2.

An FPD 1 in Embodiment 2, as in Embodiment 1 described above, is constructed by laminating, in order from bottom, a holding base 27 accommodating a light emitting mechanism 28, a gel-like adhesive sheet 32, a glass substrate 11, a carrier selective high resistance film 22, an X-ray sensitive semiconductor 14, a carrier selective high resistance film 23, a common electrode 21 and an insulating plate 25. As in Embodiment 1, spacers 24 and clamps 31 are arranged, and a curable synthetic resin 26 is poured in and enclosed.

The difference from Embodiment 1 lies in that a transparent or translucent plate 33 with planar opposite surfaces is further interposed between the gel-like adhesive sheet 32 and light emitting mechanism 28. That is, in Embodiment 2, the plate 33 is used instead of the light emitting mechanism 28 of Embodiment 1, and by interposing the adhesive sheet 32 between the glass substrate 11 and plate 33, the glass substrate 11 and plate 33 are attached as fixedly bonded together. By interposing the plate 33 between the glass substrate 11 and light emitting mechanism 28, the glass substrate 11 and light emitting mechanism 28 are fixedly attached together. As does the adhesive sheet 32, the plate 33 needs only to be transparent or translucent, i.e. needs only to be a material having light transmissivity. As in the case of the adhesive sheet 32, it is preferable to form the plate 33 with a material of higher thermal conductivity than the glass substrate 11. For the plate 33, an acrylic resin or polycarbonate resin having a powder of alumina or silica added thereto is used. As in the case of the light diffusing sheet 29a, the surface of the plate 33 opposed to the glass substrate 11 is roughened.

In Embodiment 2, the entirety of the plate 33 is made transparent or translucent in view of the property of its material. However, as in the case of the adhesive sheet 32, it need not be transparent or translucent throughout the entire area, but may be transparent or translucent only in the effective pixel area A requiring light emission from the light emitting mechanism 28. It is not absolutely necessary to be transparent or translucent in the peripheral parts other than the effective pixel area A. For example, the plate 33 used may be colored in the peripheral parts other than the effective pixel area A. The transparent or translucent plate 33 corresponds to the plate having planar opposite surfaces, and also to the substance having light transmissivity in this invention.

According to the FPD 1 in Embodiment 2 constructed as described above, the plate 33 is used as the substance having light transmissivity in Embodiment 2 in addition to the gel-like adhesive sheet 32 of Embodiment 1, to produce functions and effects similar to Embodiment 1. Since the adhesive sheet 32 and plate 33 interposed have light transmissivity, the light emitted from the light emitting mechanism 28 can, without being blocked, pass successively through the plate 33 and adhesive sheet 32 having light transmissivity, to irradiate the glass substrate 11.

By interposing the adhesive sheet 32 between the glass substrate 11 and plate 33 as in Embodiment 2, there occurs no omission of adhesion or bubbles contained between the glass substrate 11 and plate 33, as in the case of a liquid adhesive. It is possible to secure uniform irradiation with the light from the light emitting mechanism 28, while maintaining a tight contact between the glass substrate 11 and plate 33. The gel-like state of the adhesive sheet 32 assures excellent shock absorption also. Further, the plate 33 interposed between the glass substrate 11 and light emitting mechanism 28 can promote mechanical strength.

In Embodiment 2, the surface of the plate 33 opposed to the glass substrate 11 is roughened. Thus, even if bubbles are contained between the plate 33 and glass substrate 11 (e.g. in the adhesive sheet 32), light can be transmitted uniformly without boundaries of the bubbles becoming conspicuous, since the light is scattered about in multiple directions by the roughened surface.

Next, a method of manufacturing the above FPD 1 in Embodiment 2 will be described with reference to FIG. 5. FIG. 5 is a sectional view of the flat panel type X-ray detector (FPD) in a manufacturing process.

As shown in FIG. 5, the transparent or translucent plate 33 is attached to a cooling base 34, and the glass substrate 11 and plate 33 are attached as fixedly bonded together, with the gel-like adhesive sheet 32 interposed between the plate 33 and glass substrate 11. As described in Embodiments 1 and 2, the adhesive sheet 32 and plate 33, preferably, are formed of materials of larger thermal conductivity than the glass substrate 11. As the light transmissive materials formed of materials of high thermal conductivity as noted above, the adhesive sheet 32 and plate 33 are attached to the glass substrate 11 beforehand.

After the above attachment, the X-ray sensitive semiconductor 14 is laminated on the glass substrate 11. Specifically, where, for example, amorphous selenium is used for the X-ray sensitive semiconductor 14, amorphous selenium is laminated by vapor deposition on the glass substrate 11 through a vapor deposition mask 36, using an amorphous vapor deposition source 35. In the case of amorphous selenium, a thick and large film can be formed easily by a method such as vacuum evaporation. It is therefore suitable for constructing the FPD 1 which allows for a thick film with a large area. The cooling base 34 serves to check temperature increase in time of vapor deposition. The cooling base 34 is removed after the lamination, and the holding base 27 accommodating the light emitting mechanism 28 is attached.

According to this manufacture method, the light transmissive materials (i.e. adhesive sheet 32 and plate 33) formed of materials of high thermal conductivity are attached to the glass substrate 11 beforehand, whereby stress and temperature distribution can be reduced in time of forming the radiation sensitive semiconductor 14 on the glass substrate 11.

This invention is not limited to the foregoing embodiments, but may be modified as follows:

(1) The flat panel type X-ray detector (FPD) described above may be applied to an X-ray detector of an X-ray fluoroscopic apparatus. It may be applied also to an X-ray detector of an X-ray CT apparatus.

(2) In each embodiment described above, numerous switching elements are arranged two-dimensionally. Instead, only one switching element may be provided as the non-array type.

(3) In each embodiment described above, the flat panel type X-ray detector (FPD) 1 has been described by way of example. This invention is applicable to any detector having a substrate with a semiconductor layer represented by the X-ray sensitive semiconductor 14, and a planar light emitting device represented by the light emitting mechanism 28.

(4) In each embodiment described above, an X-ray detector for detecting X rays has been described by way of example. This invention is not limited to a particular type of radiation detector, but may be applied, for example, to a γ-ray detector of an ECT (Emission Computed Tomography) apparatus for detecting γ rays emitted from an object under examination administered with a radioisotope (RI). Similarly, this invention is not limited to any particular type of imaging apparatus that detects radiation, as exemplified by the above ECT apparatus.

(5) In each embodiment described above, the detector is a direct conversion type detector having a radiation (X rays in Embodiments 1 and 2) sensitive semiconductor, the radiation sensitive semiconductor acting to convert incident radiation directly into charge signals. The detector may be an indirect conversion type detector having a semiconductor of the light sensitive type, instead of the radiation sensitive type, and a scintillator, the scintillator converting incident radiation into light, and the light sensitive semiconductor converting the converted light into charge signals. In this case, the scintillator and light sensitive semiconductor correspond to the semiconductor layer in this invention.

(6) In each embodiment described above, the gel-like adhesive sheet 32 is interposed and fixedly bonded. However, it is not absolutely necessary to interpose the gel-like adhesive sheet 32. For example, the glass substrate 11 is placed in direct contact with the transparent or translucent plate 33 of Embodiment 2, and the plate 33 is interposed between the glass substrate 11 and light emitting mechanism 28. Further, the glass substrate 11 and light emitting mechanism 28 may be fixedly attached by fixing them with the clamps 31.

(7) In Embodiment 2 described above, the plate 33 has a roughened surface opposed to the glass substrate 11. It is not absolutely necessary to roughen the surface where no bubbles are contained between the plate 33 and glass substrate 11, or even if bubbles are contained, light is transmitted uniformly without boundaries of the bubbles becoming conspicuous. Similarly, in the light emitting mechanism 28 of each embodiment, the light diffusing sheet 29a has a roughened surface. It is not absolutely necessary to roughen the surface where no bubbles are contained in the side of the light diffusing sheet 29a opposed to the glass substrate 11, or even if bubbles are contained, light is transmitted uniformly without boundaries of the bubbles becoming conspicuous.

(8) In each embodiment described above, the light emitting mechanism 28 has the light guide 29 and linear light emitter 30 shown in FIGS. 3 and 4. If it is planar, the construction is not limited to what is shown in FIGS. 3 and 4. For example, a planar light emitting diode may be used as the light emitting mechanism 28.

(9) It is not necessary to form the substance represented by the adhesive sheet 32 and plate 33, with a material of higher thermal conductivity than the glass substrate 11. As long as it has light transmissivity, it may be formed of a material having lower thermal conductivity than the glass substrate. However, when laminating a semiconductor layer represented by the X-ray sensitive semiconductor 14 on the glass substrate 11 after attaching the glass substrate 11 and light emitting mechanism 28 together, it should preferably be formed of a material having higher thermal conductivity than the glass substrate since there occur stress and temperature distribution in time of forming the semiconductor layer on the substrate.

1. A radiation detector comprising a substrate having a semiconductor layer operable in response to incident radiation for converting information on said radiation into charge information, and a planar light emitting device formed on a side opposite from a radiation incidence side of the substrate, said radiation detector detecting the radiation by reading converted charge information, and removing charge information remaining in said semiconductor layer by means of light emitted from said light emitting device, characterized in that said substrate and light emitting device are attached with, interposed therebetween, a plate having planar opposite surfaces, and a roughened surface opposed to the substrate, and having light transmissivity.

2. (canceled)

3. (canceled)

4. A radiation detector as defined in claim 1, characterized in that a gel-like adhesive sheet is interposed between said substrate and said plate, to attach the substrate and the plate as fixedly adhering to each other.

5. (canceled)

6. A radiation detector as defined in claim 1 or 4, characterized in that said light emitting device includes a planar light guide device, and a linear light emitting device disposed at an end thereof, said light guide device having a light diffusing sheet opposed to the substrate, a light reflecting sheet disposed on a side remote from the substrate, and a transparent plate held between the sheets.

7. A radiation detector as defined in claim 6, characterized in that said light diffusing sheet has a roughened surface.

8. A radiation detector as defined in any one of claims 1, 4, 6 and 7, characterized in that said substance having light transmissivity is formed of a material of higher thermal conductivity than said substrate.
